(19) United States
(12) Patent Application Publication
(10) Pub. No.: US 2006/0099762 A1
(43) Pub. Date: May 11, 2006

(54) Method for manufacturing mosfet device in peripheral region

(75) Inventor: Tae Kyun Kim, Youngin-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/120,576

(22) Filed: May 2, 2005

(30) Foreign Application Priority Data
Nov. 8, 2004 (KR) 10-2004-0090415

(51) Int. Cl. H01L 21/336

(52) U.S. Cl. 438/270; 438/275; 438/305

(57) ABSTRACT

Disclosed is a method for manufacturing a MOSFET device in a peripheral region capable of avoiding degradation of electrical characteristics of the MOSFET device in the peripheral region. The method stabilizes the characteristics of the MOSFET device in the peripheral region by forming a MOSFET device selectively having a recess channel in the dense pattern region. This makes it possible to manufacture a highly-integrated MOSFET device of sub-100 nm grade.

### BACKGROUND OF THE INVENTION

1. Field of the Invention

The present invention relates to a method for manufacturing a semiconductor device, and more particularly to a method for manufacturing a MOSFET device in a peripheral region capable of avoiding degradation of electrical characteristics of the MOSFET device in the peripheral region.

2. Description of the Prior Art

As the design rule of recently developed MOSFET (metal-oxide semiconductor field-effect transistor) devices is reduced to sub-100 nm, the difference in pattern density between a dense pattern region and a loose pattern region in the corresponding peripheral region rapidly increases. Such a difference in pattern density, for example, varies the thickness of a gate spacer and results in non-uniformity in characteristics of a MOSFET device between the dense pattern region and the loose pattern region in the peripheral region.

In this regard, a method for manufacturing a MOSFET device in a peripheral region, which is currently performed in the industry, will now be described with reference to FIGS. 1A to 1D.

Referring to FIG. 1A, a trench-type isolation layer 2 is formed in a predetermined position on a silicon substrate 1 having a dense pattern region A and a loose pattern region B in the peripheral region thereof in a conventional STI (shallow trench isolation) process. A gate insulating film 3, a doped polysilicon film 4, and a tungsten silicide film 5, which are successively laminated as a gate conductive film, as well as a hard mask film 6 are formed on the entire substrate 1 including the isolation layer 2 and are then patterned to form a gate 7 in each of the dense pattern region A and the loose pattern region B of the substrate 1.

Referring to FIG. 1B, a gate re-oxidation process is performed to grow a screen oxide film 8 on the lateral walls of the gate 7 and the surface of the substrate 1. Subsequently, LDD (lightly doped drain) implantation is performed to form LDD regions 9 in the substrate surface at both sides of the gate 7, respectively.

Referring to FIG. 1C, a gate buffer oxide film 10, a gate spacer nitride film 11, and a gate spacer oxide film 12 are successively deposited on the entire substrate to form a gate spacer lamination film having ONO (oxide-nitride-oxide) structure.

Referring to FIG. 1D, a series of conventional MOSFET manufacturing processes, that is, an N+/P+ mask process, a spacer etching process, and an N+/P+ implantation process are successively performed to form gate spacers 13 on both lateral walls of the gate 7, respectively, and source/drain regions 14 within the substrate surface on both sides of the gate 7, including the gate spacers 13, respectively. This completes the manufacturing of a MOSFET device in the dense pattern region A and loose pattern region B of the peripheral region.

However, the above-mentioned method for manufacturing a MOSFET device in the peripheral region has a problem as follows:

The gate spacer oxide film 12 as in FIG. 1C usually has a thickness substantially larger than that of the gate buffer oxide film 10 and the gate spacer nitride film 11. Meanwhile, film deposition has different deposition loading effect depending on pattern density and the deposition thickness has dependency on pattern density. Particularly, the higher the pattern density is, the smaller the deposition thickness becomes. Such dependency on pattern density becomes severer as the film thickness increases.

As the design rule of MOSFET devices is reduced to sub-100 nm, therefore, the difference in deposition thickness between the dense pattern region and the loose pattern region in the peripheral region of the gate spacer oxide film is as large as hundreds of Å. As a result, the gate spacer thickness of the MOSFET devices in the finally-formed peripheral region is not uniform. In the end, this results in degradation of electrical characteristics, including Vtsat (saturation threshold voltage), of the MOSFET devices. Such a problem is particularly fatal to future development of a highly-integrated MOSFET device.

In order to manufacture a highly-integrated MOSFET device, consequently, it is necessary to secure the electrical characteristics of the MOSFET device in the peripheral region. However, there is a limitation in improving the loading effect, which is inherent property of the material, when depositing the gate spacer oxide film. Therefore, a structural approach regarding the MOFSET device is required to solve the above problem.

### SUMMARY OF THE INVENTION

Accordingly, the present invention has been made to solve the above-mentioned problems occurring in the prior art, and an object of the present invention is to provide a method for manufacturing a MOSFET device in a peripheral region capable of avoiding degradation of electrical characteristics of the MOSFET device in the peripheral region.

Another object of the present invention is to provide a method for manufacturing a MOSFET device in a peripheral region capable of manufacturing a highly-integrated MOSFET device of sub-100 nm grade by avoiding degradation of electrical characteristics of the MOSFET device in the peripheral region.

In order to accomplish these objects, there is provided a method for manufacturing a MOSFET device in a peripheral region including the steps of forming a isolation layer to define an active region in a predetermined position on a silicon substrate having a dense pattern region and a loose pattern region in the peripheral region thereof; forming a groove to obtain a recess channel on the surface of a part of the substrate on which a gate is to be formed in the dense pattern region; forming a gate insulating film, a gate conductive film, and a hard mask film successively on the entire substrate including the isolation layer and the groove; forming gates on the groove in the dense pattern region and on the substrate surface in the loose pattern region, respectively, by patterning the hard mask film, the gate conductive film, and the gate insulating film; forming LDD regions within the substrate surface on both sides of the gates, respectively; depositing a gate buffer oxide film, a gate spacer nitride film, and a gate spacer oxide film successively on the resulting substrate which has been subject to the previous steps; etching the gate spacer oxide film, the gate spacer nitride film, and the gate buffer oxide film to form gate spacers on both lateral walls of the gates, respectively; and, forming source/drain regions within the substrate surface on both sides of the gates including the gate spacers, respectively.

The step of forming a groove on the surface of a part of the substrate on which a gate is to be formed in the dense pattern region includes a first process of forming a sacrificial oxide film and a mask polysilicon film on the entire substrate having the isolation layer formed thereon; a second process of etching a part of the mask polysilicon film above a part of the substrate on which a gate is to be formed in the dense pattern region and a part of the sacrificial oxide film below the part of the mask polysilicon film, as well as etching the substrate with a predetermined thickness; and a third process of removing the mask polysilicon film and the sacrificial oxide film.

The sacrificial oxide film is formed with a thickness of 100-200 Å, the mask polysilicon film is formed with a thickness of 1000-1500 Å, and the groove is formed with a depth of 300-1000 Å.

The method for manufacturing a MOSFET device in a peripheral region further includes a step of performing well implant, channel stop implant, and threshold voltage adjustment implant after the step of forming a groove and before the step of forming a gate insulating film, a gate conductive film, and a hard mask film successively.

The gate insulating film is an oxide film, the gate conductive film is a lamination film of a doped polysilicon film and a tungsten silicide film, and the hard mask film is a nitride film. The oxide film is formed with a thickness of 30-50 Å, the doped polysilicon film is formed with a thickness of 400-700 Å, the tungsten silicide film is formed with a thickness of 1000-1500 Å, and the nitride film is formed with a thickness of 2000-2500 Å.

The method for manufacturing a MOSFET device in a peripheral region further includes a step of subjecting the resulting substrate having gates formed thereon to a gate re-oxidation process to form a screen oxide film on the lateral wall of the gates and on the substrate surface after the step of forming gates and before the step of forming LDD regions. The gate re-oxidation process is performed while making it a target to grow the screen oxide film with a thickness of 30-60 Å.

The gate buffer oxide film is deposited with a thickness of 80-120 Å, the gate spacer nitride film is deposited with a thickness of 90-150 Å, and the gate spacer oxide film is deposited with a thickness of 400-600 Å.

### BRIEF DESCRIPTION OF THE DRAWINGS

The above and other objects, features and advantages of the present invention will be more apparent from the following detailed description taken in conjunction with the accompanying drawings, in which:

FIGS. 1A to 1D are sectional views showing processes of a conventional method for manufacturing a MOSFET device in a peripheral region and

FIGS. 2A to 2F are sectional views showing processes of a method for manufacturing a MOSFET device in a peripheral region according to the present invention.

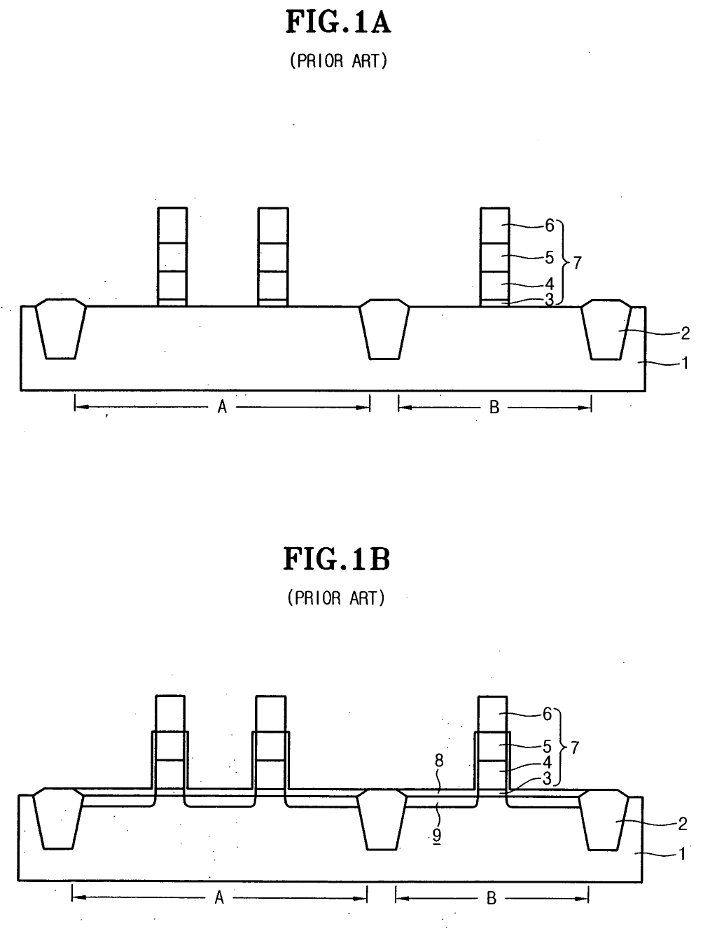

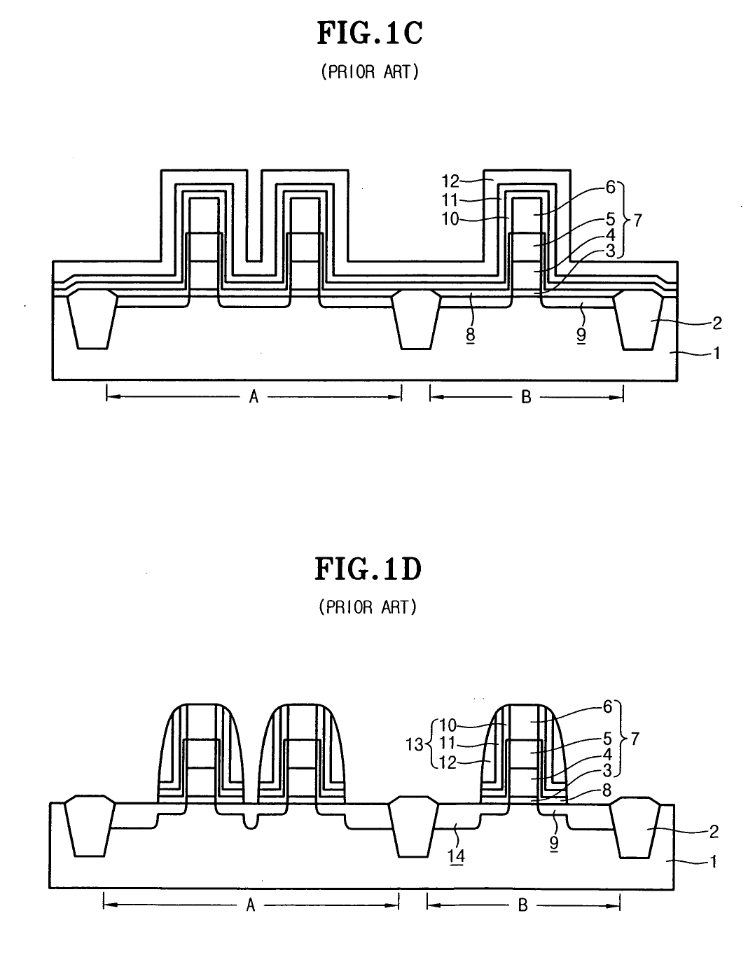

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

The present invention selectively applies a recess channel to a dense pattern region of a peripheral region to increase the effective channel length of a MOSFET device. As a result, Vtsat of the MOSFET device formed on the dense pattern region of the peripheral region increases. In this case, decrease in Vtsat of the MOSFET device in the dense pattern region caused by the dependency on pattern density of the relatively thin gate spacer is compensated for by formation of the recess channel. Consequently, degradation of electrical characteristics of the MOSFET device in the peripheral region is avoided and a highly-integrated MOSFET device can be manufactured.

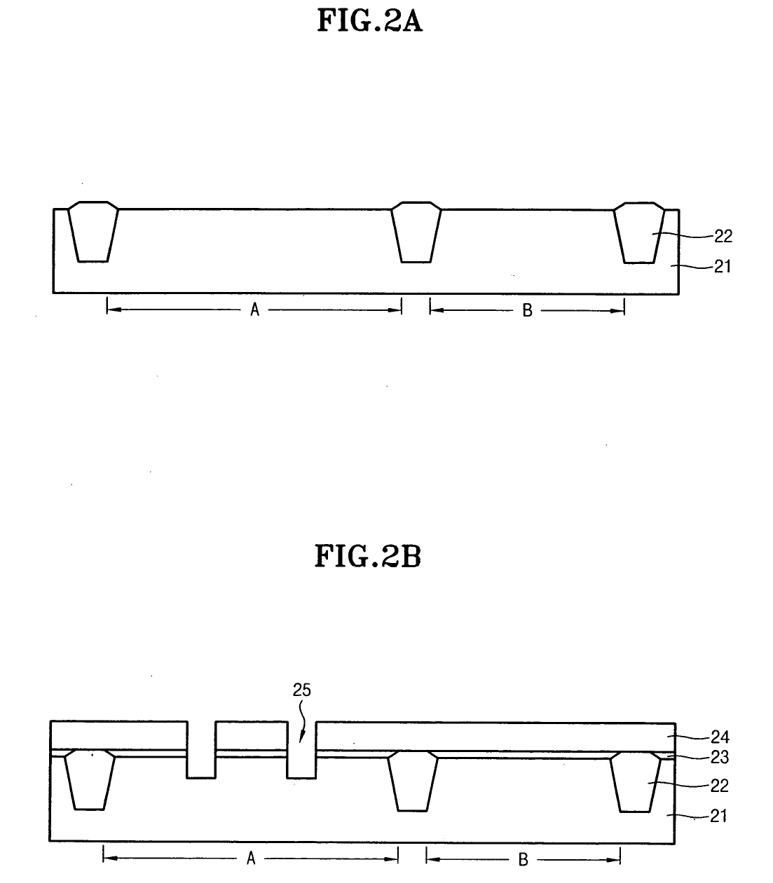

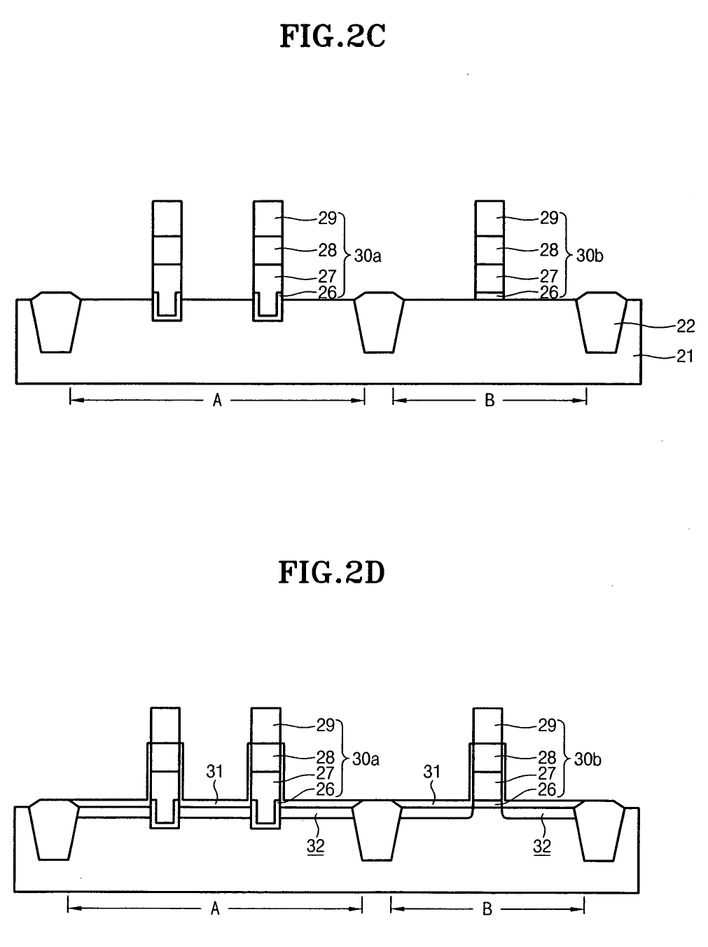

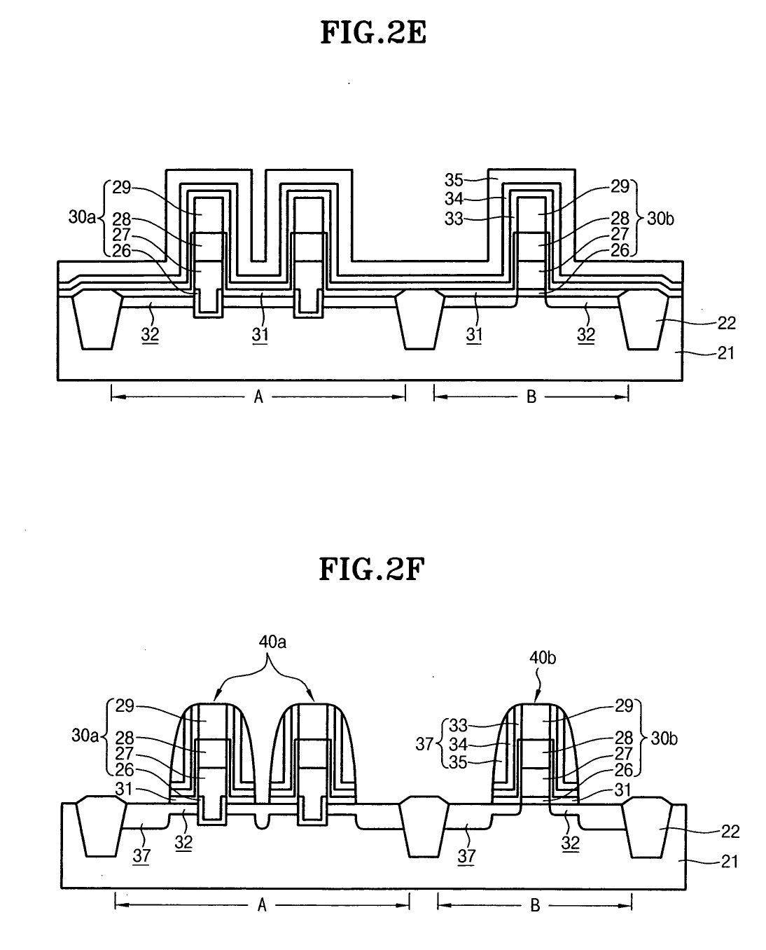

A method for manufacturing a MOSFET device in a peripheral region according to the present invention will now be described in more detail with reference to FIGS. 2A to 2F, which are sectional views showing respective processes thereof regarding the peripheral region.

Referring to FIG. 2A, a silicon substrate 21 divided into a cell region and a peripheral region and having a dense pattern region A and a loose pattern region B positioned in the peripheral region is provided. Subsequently, trench-type isolation layer 22 are formed on predetermined positions of the silicon substrate 21 in a conventional STI process to define an active region.

Referring to FIG. 2B, a sacrificial oxide film 23 and a mask polylicon film 24 are formed on the entire substrate 21, including the isolation layer 22, with a thickness of 100-200 Å and 1000-1500 Å, respectively, as etching barriers to selectively form a recess channel in the dense pattern region A. Subsequently, a part of the mask polysilicon film positioned above a part of the substrate on which a recess channel is to be formed, particularly a part of the dense pattern region A of the substrate on which a gate of is to be formed, and a part of the sacrificial oxide film below it are etched. The exposed part of the substrate is then etched with a predetermined depth, for example 300-1000 Å, to form a groove 25.

Referring to FIG. 2C, wet and dry etching processes are performed to remove the remaining mask polysilicon film and the sacrificial oxide film. A series of conventional implantation processes, particularly a well implant process, a channel stop implant process, and a threshold voltage (Vt) adjustment implant process are then performed successively.

On the resulting substrate having the groove 25 selectively recessed in the dense pattern region A, a gate insulating film 26 made of an oxide film, a doped polysilicon film 27, and a tungsten silicide film 28 are successively formed as gate conductive films, on which a hard mask film 29 made of a nitride film is formed. These laminated films are patterned to gates 30a and 30b on the groove 25 in the dense pattern region A and on the substrate surface in the loose pattern region B, respectively. During patterning, the laminated films must be accurately aligned to form the gate. 30a on the groove 25 in the dense pattern region A.

The oxide film is formed with a thickness of 30-50 Å, the doped polysilicon film is formed with a thickness of 400-700 Å, the tungsten silicide film is formed with a thickness of 1000-1500 Å, and the nitride film is formed with a thickness of 2000-2500 Å.

Referring to FIG. 2D, the resulting substrate is subject to a gate re-oxidation process to grow a screen oxide film 31 on the lateral wall of the gates 30a and 30b and the surface of the substrate 21. The gate re-oxidation process is preferably performed while making it a target to grow the screen oxide film 31 with a thickness of 30-60 Å.

The resulting substrate is then subject to LDD implantation to form LDD regions 32 within the substrate surface on both sides of the gates 30a and 30b, respectively.

Referring to FIG. 2E, a buffer oxide film 33 of a thickness of 80-120 Å, a gate spacer nitride film 34 of a thickness of 90-150 Å, and a gate spacer oxide film 35 of a thickness of 400-600 Å are successively deposited on the resulting substrate to form a gate spacer lamination film of ONO structure. Although not shown in detail, the gate spacer oxide film 35 is deposited with different thicknesses between the dense pattern region A and the loose pattern region B of the peripheral region, due to dependency on pattern density. Particularly, the thickness of the gate spacer oxide film 35 deposited in the dense pattern region A is smaller than that in the loose pattern region B.

Referring to FIG. 2F, the resulting substrate is subject to a series of conventional processes including an N+/P+ mask process, a spacer etching process, and an N+/P+ implantation processes are successively performed to form gate spacers 36 on both lateral walls of the gates 30a and 30b, respectively, and source/drain regions 37 within the substrate surface on both sides of the gates 30a and 30b, including the gate spacers 36, respectively. As a result, highly-integrated MOSFET devices 40a and 40b are formed in the dense pattern region A and the loose pattern region B of the peripheral region, respectively.

The thickness of the gate spacers 36 of the MOSFET device 40a formed in the dense pattern region A of the peripheral region has dependency on pattern density and is different from that of the MOSFET device 40b formed in the loose pattern region B. The electrical characteristics, including Vtsat, of the MOSFET device 40a formed in the dense pattern region A may then degrade.

However, the MOSFET device 40a formed in the dense pattern region A is provided with a recess channel and has an effective channel length larger than that of the MOSFET device 40b formed in the loose pattern region B. Consequently, the MOSFET device 40a formed in the dense pattern region A has an increased Vtsat.

As a result, the increase in Vtsat caused by the increased effective channel length compensates for the decrease in Vtsat resulting form the difference in thickness of the gate spacers. Therefore, the MOSFET device 40a formed in the dense pattern region A according to the present invention has stable electrical characteristics.

As mentioned above, the present invention can stabilize the characteristics of the MOSFET device in the peripheral region by forming a MOSFET device selectively having a recess channel in the dense pattern region. This makes it possible to manufacture a highly-integrated MOSFET device of sub-100 nm grade in the future.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for manufacturing a MOSFET device in a peripheral region comprising the steps of:
forming a an isolation layer to define an active region in a predetermined position on a silicon substrate having a dense pattern region and a loose pattern region in the peripheral region thereof;
forming a groove to obtain a recess channel on the surface of a part of the substrate on which a gate is to be formed in the dense pattern region;
forming a gate insulating film, a gate conductive film, and a hard mask film successively on the entire substrate including the isolation layer and the groove;
forming gates on the groove in the dense pattern region and on the substrate surface in the loose pattern region, respectively, by patterning the hard mask film, the gate conductive film, and the gate insulating film;
forming LDD regions within the substrate surface on both sides of the gates, respectively;
depositing a gate buffer oxide film, a gate spacer nitride film, and a gate spacer oxide film successively on the resulting substrate which has been subject to the previous steps;
etching the gate spacer oxide film, the gate spacer nitride film, and the gate buffer oxide film to form gate spacers on both lateral walls of the gates, respectively; and
forming source/drain regions within the substrate surface on both sides of the gates including the gate spacers, respectively.

2. The method for manufacturing a MOSFET device in a peripheral region as claimed in claim 1, wherein the step of forming a groove on the surface of a part of the substrate on which a gate is to be formed in the dense pattern region comprises:
a first process of forming a sacrificial oxide film and a mask polysilicon film on the entire substrate having the isolation layer formed thereon;
a second process of etching a part of the mask polysilicon film above a part of the substrate on which a gate is to be formed in the dense pattern region and a part of the sacrificial oxide film below the part of the mask polysilicon film, as well as etching the substrate with a predetermined thickness; and
a third process of removing the mask polysilicon film and the sacrificial oxide film.

3. The method for manufacturing a MOSFET device in a peripheral region as claimed in claim 2, wherein in the sacrificial oxide film is formed with a thickness of 100-200 Å and the mask polysilicon film is formed with a thickness of 1000-1500 Å.

4. The method for manufacturing a MOSFET device in a peripheral region as claimed in claim 1, wherein the groove is formed with a depth of 300-1000 Å.

5. The method for manufacturing a MOSFET device in a peripheral region as claimed in claim 1, further comprising a step of performing well implant, channel stop implant, and threshold voltage adjustment implant after the step of forming a groove and before the step of forming a gate insulating film, a gate conductive film, and a hard mask film successively.

6. The method for manufacturing a MOSFET device in a peripheral region as claimed in claim 1, wherein the gate insulating film is an oxide film, the gate conductive film is a lamination film of a doped polysilicon film and a tungsten silicide film, and the hard mask film is a nitride film.

7. The method for manufacturing a MOSFET device in a peripheral region as claimed in claim 6, wherein the oxide film is formed with a thickness of 30-50 Å, the doped polysilicon film is formed with a thickness of 400-700 Å, the tungsten silicide film is formed with a thickness of 1000-1500 Å and the nitride film is formed with a thickness of 2000-2500 Å.

8. The method for manufacturing a MOSFET device in a peripheral region as claimed in claim 1, further comprising a step of subjecting the resulting substrate having gates formed thereon to a gate re-oxidation process to form a screen oxide film on the lateral wall of the gates and on the substrate surface after the step of forming gates and before the step of forming LDD regions.

9. The method for manufacturing a MOSFET device in a peripheral region as claimed in claim 8, wherein the gate re-oxidation process is performed while making it a target to grow the screen oxide film with a thickness of 30-60 Å.

10. The method for manufacturing a MOSFET device in a peripheral region as claimed in claim 1, wherein the gate buffer oxide film is deposited with a thickness of 80-120 Å, the gate spacer nitride film is deposited with a thickness of 90-150 Å, and the gate spacer oxide film is deposited with a thickness of 400-600 Å.

11. The method for manufacturing a MOSFET device in a peripheral region as claimed in claim 2, wherein the groove is formed with a depth of 300-1000 Å.
